(19) United States
(12) Patent Application Publication
(10) Pub. No.: US 2013/0034935 A1
(43) Pub. Date: Feb. 7, 2013

(54) DICING DIE-BONDING FILM

(71) Applicant: Takeshi MATSUMURA, Osaka (JP)

(72) Inventor: Takeshi MATSUMURA, Osaka (JP)

(21) Appl. No.: 13/564,920

(22) Filed: Aug. 2, 2012

(30) Foreign Application Priority Data
Aug. 5, 2011 (JP) 2011-172099

(51) Int. Cl. H01L 21/50; C09J 7/02

(52) U.S. Cl. 438/118; 428/354; 257/E21.499

(57) ABSTRACT

Provide is a dicing die-bonding film that prevents the occurrence of reflow cracking and that is capable of manufacturing a semiconductor device having excellent reliability with good productivity. The dicing die-bonding film of the present invention comprises at least: a dicing film in which a pressure-sensitive adhesive layer is provided on a support base material; and a die-bonding film that is provided on the pressure-sensitive adhesive layer, wherein the dicing die-bonding film has a water absorption rate of 1.5% by weight or less calculated from the following formula (1).

[Numerical Formula 1]

[(M2−M1)/M1]×100=Water absorption rate(% by weight) (1)
(wherein, M1 represents the initial weight of the dicing die-bonding film, and M2 represents the weight after the dicing die-bonding film is left under an atmosphere of 85° C. and 85% RH for 120 hours to absorb moisture.)

### BACKGROUND OF THE INVENTION

1. Field of the Invention

The present invention relates to a dicing die-bonding film that is used in a method of manufacturing a semiconductor device for example.

2. Description of the Related Art

In a conventional method of manufacturing a semiconductor device, a thickness of a semiconductor wafer on which a circuit pattern is formed is adjusted as necessary by backside grinding, and then it is diced into semiconductor chips (a dicing step). In the dicing step, cutting water (normally having a hydraulic fluid pressure of about 2 kg/cm²) is generally sprayed for cooling or preventing cut scraps from scattering.

Then, the semiconductor chip is fixed to an adherend such as a lead frame with an adhesive (a mounting step), and then it is transferred to a bonding step. In the mounting step, the adhesive is applied onto the lead frame or the semiconductor chip. However, it is difficult to obtain a uniform adhesive layer with this method, and a special apparatus and a long period of time are necessary for the application of the adhesive. Because of this, a dicing die-bonding film has been proposed in Japanese Patent Application Laid-Open No. 60-57642 having an adhesive layer (a die-bonding film) for fixing a chip that is necessary in the mounting step while adhering and holding a semiconductor wafer in the dicing step.

In the dicing die-bonding film, the die-bonding film is formed on a dicing film in a peelable manner. That is, after a semiconductor wafer is diced while being held by the die-bonding film, the dicing film is then stretched to peel the semiconductor chips with the die-bonding film, and they are individually collected to be fixed to an adherend such as a lead frame through the die-bonding film.

On the other hand, a demand for high density mounting due to smaller and thinner electronic equipment has been rapidly increasing in recent years. Because of this, a surface mounting type semiconductor package that is suitable for high density mounting has been mainstream in place of the conventional pin insert type semiconductor package. In the surface mounting type, a lead is directly soldered to a printed circuit board, etc. Because of this, the whole package is heated with a heating method such as infrared reflow, vapor phase reflow, or solder dip to be mounted. Because the whole package is exposed to a high temperature of 210 to 260° C. in heating, a package crack (referred to as “reflow cracking” below) occurs due to explosive vaporization of the moisture when there is moisture inside of the package.

A mechanism of generating reflow cracking caused by the die-bonding film is as follows. That is, when a large amount of moisture is absorbed in the die-bonding film, the moisture evaporates due to heating during mounting of reflow soldering, damaging or peeling of the die-bonding film due to the vapor pressure occurs, and reflow cracking occurs.

The reflow cracking caused by the moisture absorption of the die-bonding film has been a serious problem because it significantly reduces reliability of especially a thin semiconductor package while the reflow cracking resistance of a sealing resin has been improved, and improvement of the reflow cracking resistance of the die-bonding film has been highly demanded.

### SUMMARY OF THE INVENTION

The present invention is performed in view of the above-described problems, and an objective of the invention is to provide a dicing die-bonding film that prevents the occurrence of reflow cracking and that is capable of manufacturing a semiconductor device having excellent reliability with good productivity.

As a result of investigation in order to achieve the above-described objective, the present inventors have found that moisture absorption of the die-bonding film occurs when moisture migrates from a dicing film while the die-bonding film is stored as a dicing die-bonding film, due to cutting water that is used when dicing a semiconductor wafer, and when the die-bonding film is stored as a semiconductor package, and the present invention has been completed.

That is, a dicing die-bonding film according to the present invention has at least a dicing film in which a pressure-sensitive adhesive layer is provided on a support base material and a die-bonding film that is provided on the pressure-sensitive adhesive layer, wherein the dicing die-bonding film has a water absorption rate of 1.5% by weight or less calculated from the following formula (1).

[Numerical Formula 1]

[(M2−M1)/M1]×100=Water absorption rate(% by weight) (1)

(wherein, M1 represents the initial weight of the dicing die-bonding film, and M2 represents the weight after the dicing die-bonding film is left under an atmosphere of 85° C. and 85% RH for 120 hours to absorb moisture.)

In the present invention, by adjusting the water absorption rate of the entire dicing die-bonding film to 1.5% by weight or less according to the above-described configuration, for example, the die-bonding film can be prevented from excessively absorbing moisture in the dicing film while the dicing die-bonding film is stored and reflow cracking can be prevented from occurring in a subsequent reflow step. In addition, for example, when a semiconductor wafer is diced, permeation of water into the interface between the dicing film and the die-bonding film can be also prevented that is caused by moisture absorption of the dicing film and the die-bonding film from the cutting water that is used in the dicing step.

In the above-described configuration, the dicing film has a water absorption rate of 1.5% by weight or less calculated from the following formula (2).

[Numerical Formula 2]

[(M4−M3)/M3]×100=Water absorption rate(% by weight) (2)

(wherein, M3 represents the initial weight of the dicing film, and M4 represents the weight after the dicing film is left under an atmosphere of 85° C. and 85% RH for 120 hours to absorb moisture.)

By adjusting the water absorption rate of the dicing film to 1.5% by weight or less according to the above-described configuration, the water content can be reduced in the dicing film that is absorbed by the die-bonding film while the dicing die-bonding film is stored. As a result, the occurrence of reflow cracking in the reflow step can be further prevented.

In the above-described configuration, the die-bonding film has a water absorption rate of 1.5% by weight or less calculated from the following formula (3).

[Numerical Formula 3]

[(M6−M5)/M5]×100=Water absorption rate(% by weight) (3)

(wherein, M5 represents the initial weight of the die-bonding film, and M6 represents the weight after the die-bonding film is left under an atmosphere of 85° C. and 85% RH for 120 hours to absorb moisture.)

By adjusting the water absorption rate of the die-bonding film to 1.5% by weight or less according to the above-described configuration, the amount of water can be reduced that is absorbed by the die-bonding film from the dicing film while the dicing die-bonding film is stored. As a result, the occurrence of reflow cracking in the reflow step can be further prevented. In addition, the water content that is absorbed by the die-bonding film can be reduced as well while the semiconductor package, in which the semiconductor chip is die-bonded on an adherend such as a lead frame by the die-bonding film and sealed by a sealing resin, is stored.

According to the present invention, by adjusting the water absorption rate of the entire dicing die-bonding film itself to 1.5% by weight or less, for example, the die-bonding film can be prevented from excessively absorbing moisture in the dicing film while the dicing die-bonding film is stored. In addition, when a semiconductor wafer is diced, permeation of water into the interface between the dicing film and the die-bonding film can be also prevented that is caused by moisture absorption of the dicing film and the die-bonding film from the cutting water that is used in the dicing step. That is, with the dicing die-bonding film of the present invention, the occurrence of reflow cracking in the reflow step can be further prevented compared with a conventional dicing die-bonding film, and a semiconductor device having excellent moisture-resistance reliability can be manufactured.

### BRIEF DESCRIPTION OF THE DRAWINGS

FIG. 1 is a schematic sectional view showing a dicing die-bonding film according to one embodiment of the present invention; and

FIG. 2 is a schematic sectional view showing another dicing die-bonding film according to another embodiment of the present invention.

### DETAILED DESCRIPTION OF THE PREFERRED EMBODIMENTS

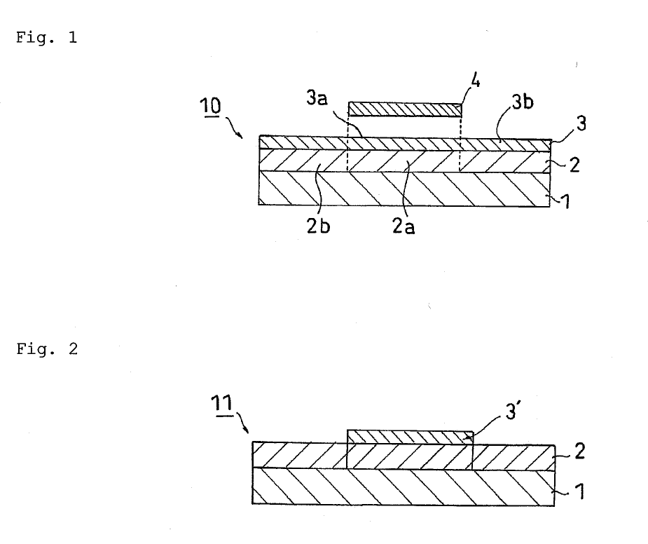

An embodiment according to the present invention will be described with reference to the drawings. FIG. 1 is a schematic sectional view showing one example of a dicing die-bonding film according to the present embodiment. As shown in FIG. 1, a dicing die-bonding film 10 includes at least a dicing film in which a pressure-sensitive adhesive layer 2 is provided on a support base material 1, and a die-bonding film 3 that is provided on the pressure-sensitive adhesive layer 2. However, as shown in FIG. 2, the present invention may be a dicing die-bonding film 11 having a configuration in which a die-bonding film 3′ is formed only on a semiconductor wafer pasting portion 2a.

Each of the dicing die-bonding films 10 and 11 has a water absorption rate of 1.5% by weight or less, preferably 1.2% by weight or less, and more preferably 1.0% by weight or less. By adjusting the water absorption rate to 1.5% by weight or less, reflow cracking is prevented that occurs when the die-bonding films 3 and 3′ excessively absorb moisture in the dicing film while the dicing die-bonding films 10 and 11 are stored. In addition, when a semiconductor wafer 4 is diced, permeation of water into the interface between the dicing film and the die-bonding film 3 and between the dicing film and the die-bonding film 3′ can be also prevented that is caused by moisture absorption of the dicing film and the die-bonding films 3 and 3′ from the cutting water that is used in the dicing step. As the lower limit of the water absorption rate of each of the dicing die-bonding films 10 and 11 is lower, it is better from the viewpoint of the effect of the present invention. It is substantially 0%, and preferably 0%. The water absorption rate of each of the entire dicing die-bonding films 10 and 11 can be controlled by appropriately adjusting the water absorption rate of the dicing film (in more detail, the water absorption rates of the support base material 1 and the pressure-sensitive adhesive layer 2) and the water absorption rates of the die-bonding films 3 and 3′ that configure the dicing die-bonding film. A method of adjusting the water absorption rates of the dicing film and the die-bonding films 3 and 3′ will be described later.

The water absorption rate of each of the dicing die-bonding films 10 and 11 can be obtained as follows. A sample of 20 mm×20 mm is cut out from each of the dicing die-bonding films 10 and 11. The sample is left in a vacuum dryer at 120° C. for 3 hours to be dried. Then, it is left and cooled in a desiccator, and the dry weight M1 of the sample is measured. The sample is then left in a constant temperature and humidity chamber under an atmosphere of 85° C. and 85% RH for 120 hours to allow the sample to absorb moisture. Then, the sample is taken out and weighed. When the weighed value becomes constant, it is defined as M2. The water absorption rate is calculated based on the following formula (1) from the measured M1 and M2.

[Numerical Formula 4]

[(M2−M1)/M1]×100=Water absorption rate(% by weight) (1)

(wherein, M1 represents the initial weight of the dicing die-bonding film, and M2 represents the weight after the dicing die-bonding film is left under an atmosphere of 85° C. and 85% RH for 120 hours to absorb moisture.)

The dicing film according to the present embodiment has a structure in which at least the pressure-sensitive adhesive layer 2 is provided on the support base material 1. The dicing film has a water absorption rate of 1.5% by weight or less, preferably 1.2% by weight or less, and more preferably 1.0% by weight or less. By adjusting the water absorption rate to 1.5% by weight or less, the water content can be reduced in the dicing film (especially in the pressure-sensitive adhesive layer 2) that is absorbed by the die-bonding films 3 and 3′ while the dicing die-bonding films 10 and 11 are stored. As a result, the occurrence of reflow cracking in the reflow step can be further prevented. In addition, when the semiconductor wafer 4 is diced, permeation of water into the interface between the dicing film and the die-bonding film 3 and between the dicing film and the die-bonding film 3′ can be also prevented that is caused by moisture absorption of the dicing film from the cutting water that is used in the dicing step. As the lower limit of the water absorption rate of the dicing film is lower, it is better from the viewpoint of the effect of the present invention. It is substantially 0%, and preferably 0%.

The water absorption rate of the dicing film can be controlled by appropriately adjusting the water absorption rates of the support base material 1 and the pressure-sensitive adhesive layer 2 that configure the dicing film. A method of adjusting the water absorption rates of the support base material 1 and the pressure-sensitive adhesive layer 2 will be described later.

The water absorption rate of the dicing film can be obtained as follows. A sample of 20 mm×20 mm is cut out from the dicing film. The sample is left in a vacuum dryer at 120° C. for 3 hours to be dried. Then, it is left and cooled in a desiccator, and the dry weight M3 of the sample is measured. The sample is then left in a constant temperature and humidity chamber under an atmosphere of 85° C. and 85% RH for 120 hours to allow the sample to absorb moisture. Then, the sample is taken out and weighed. When the weighed value becomes constant, it is defined as M4. The water absorption rate is calculated based on the following formula (2) from the measured M3 and M4.

[Numerical Formula 5]

[(M4−M3)/M3]×100=Water absorption rate(% by weight) (2)

(wherein, M3 represents the initial weight of the dicing film, and M4 represents the weight after the dicing film is left under an atmosphere of 85° C. and 85% RH for 120 hours to absorb moisture.)

The support base material 1 becomes a strength matrix of the dicing die-bonding films 10 and 11, and the support base material 1 preferably has a lower water absorption rate. However, it is not especially limited at least if the water absorption rate of each of the entire dicing die-bonding films 10 and 11 can be 1.5% by weight or less, and preferably if the water absorption rate of the entire dicing film can be 1.5% by weight or less. Specifically, the water absorption rate is preferably 1.5% by weight or less, more preferably 1.2% by weight or less, and especially preferably 1.0% by weight or less. As the lower limit of the water absorption rate of the support base material 1 is lower, it is better from the viewpoint of the effect of the present invention. It is substantially 0%, and preferably 0%.

The water absorption rate of the support base material 1 can be controlled by optimizing conditions of film formation, material design, etc.

The water absorption rate of the support base material 1 can be obtained as follows. A sample of 20 mm×20 mm is cut out from the support base material 1. The sample is left in a vacuum dryer at 120° C. for 1 hour to be dried. Then, it is left and cooled in a desiccator, and the dry weight M7 of the sample is measured. The sample is then left in a constant temperature and humidity chamber under an atmosphere of 85° C. and 85% RH for 120 hours to allow the sample to absorb moisture. Then, the sample is taken out and weighed. When the weighed value becomes constant, it is defined as M8. The water absorption rate is calculated based on the following formula (4) from the measured M7 and M8.

[Numerical Formula 6]

[(M8−M7)/M7]×100=Water absorption rate(% by weight) (4)

(wherein, M7 represents the initial weight of the support base material, and M8 represents the weight after the support base material is left under an atmosphere of 85° C. and 85% RH for 120 hours to absorb moisture.)

Examples of the support base material 1 include specifically ones made of: polyolefin such as low-density polyethylene, straight chain polyethylene, intermediate-density polyethylene, high-density polyethylene, very low-density polyethylene, random copolymer polypropylene, block copolymer polypropylene, homopolypropylene, polybutene, and polymethylpentene; an ethylene-vinylacetate copolymer; an ionomer resin; an ethylene(meth)acrylic acid copolymer; an ethylene(meth)acrylic acid ester (random or alternating) copolymer; an ethylene-butene copolymer; an ethylene-hexene copolymer; polyurethane; polyester such as polyethyleneterephthalate and polyethylenenaphthalate; polycarbonate; polyetheretherketone; polyimide; polyetherimide; polyamide; whole aromatic polyamides; polyphenylsulfide; aramid (paper); glass; glass cloth; a fluorine resin; polyvinyl chloride; polyvinylidene chloride; a cellulose resin; a silicone resin; metal (foil); and paper, and the like. Among these, polyethylene and polypropylene and the like are preferable as the support base material 1 because of low water absorption rate.

An example of a material of the support base material 1 is a polymer such as a cross-linked body of the resins described above. The plastic films may be used in a non-stretched state or may be used in a uniaxially or biaxially stretched state as necessary. With a resin sheet to which a heat shrinking property is imparted by a stretching treatment or the like, the adhering area of the pressure-sensitive adhesive layer 2 to the die-bonding films 3 and 3′ can be reduced by heat-shrinking the support base material 1 after dicing, and the semiconductor chips (semiconductor elements) can be collected easily.

A known surface treatment such as a chemical or physical treatment such as a chromate treatment, ozone exposure, flame exposure, high voltage electric exposure, and an ionized ultraviolet treatment, and a coating treatment by an undercoating agent (for example, a tacky substance described later) can be performed on the surface of the support base material 1 in order to improve adhesiveness, holding properties, etc. with the adjacent layer. The same type or different type of support base material can be appropriately selected and used as the support base material 1, and a support base material in which a plurality of types are blended can be used depending on necessity. Further, a vapor-deposited layer of a conductive substance composed of a metal, an alloy, an oxide thereof, etc. and having a thickness of about 30 to 500 angstrom can be provided on the support base material 1 in order to give an antistatic function to the support base material 1. The support base material 1 may be a single layer or a multi layer of two or more types. When the pressure-sensitive adhesive layer 2 is a radiation curing type layer, the support base material 1 is preferably one that at least partially transmits radiation such as an X ray, an ultraviolet ray, or an electron beam.

The thickness of the support base material 1 can be appropriately decided without limitation particularly. However, it is generally about 5 to 200 μm.

As the pressure-sensitive adhesive layer 2, one that has a lower water absorption rate is preferable. However, it is not especially limited if the water absorption rate of each of the entire dicing die-bonding films 10 and 11 can be 1.5% by weight or less, and preferably if the water absorption rate of the entire dicing film can be 1.5% by weight or less.

Specifically, the water absorption rate is preferably 1.5% by weight or less, more preferably 1.2% by weight or less, and especially preferably 1.0% by weight or less. As the lower limit of the water absorption rate of the pressure-sensitive adhesive layer 2 is lower, it is better from the viewpoint of the effect of the present invention. It is substantially 0%, and preferably 0%.

The water absorption rate of the pressure-sensitive adhesive layer 2 can be controlled by performing optimization of manufacturing conditions, material design, etc.

The water absorption rate of the pressure-sensitive adhesive layer 2 can be obtained as follows. A sample of 20 mm×20 mm is cut out from the pressure-sensitive adhesive layer 2. The sample is left in a vacuum dryer at 120° C. for 3 hours to be dried. Then, it is left and cooled in a desiccator, and the dry weight M9 of the sample is measured. The sample is then left in a constant temperature and humidity chamber under an atmosphere of 85° C. and 85% RH for 120 hours to allow the sample to absorb moisture. Then, the sample is taken out and weighed. When the weighed value becomes constant, it is defined as M10. The water absorption rate is calculated based on the following formula (5) from the measured M9 and M10.

[Numerical Formula 7]

[(M10−M9)/M9]×100=Water absorption rate(% by weight) (5)

(wherein, M9 represents the initial weight of the pressure-sensitive adhesive layer, and M10 represents the weight after the pressure-sensitive adhesive layer is left under an atmosphere of 85° C. and 85% RH for 120 hours to absorb moisture.)

The pressure-sensitive adhesive that is used to form the pressure-sensitive adhesive 2 is not especially limited. However, radiation curing-type pressure-sensitive adhesive is suitable in which a difference of adhesive strength can be provided in every region of the surface of the layer. In this case, before being pasted to the die-bonding films 3 and 3′, the pressure-sensitive adhesive layer 2 may be cured by irradiation with radiation in advance or may not be cured. In case of conducting radiation curing, the cured portion may not be necessarily the entire region of the pressure-sensitive adhesive layer 2, and at least a portion 2a in the pressure-sensitive adhesive layer 2 corresponding to a wafer pasting portion 3a of the die-bonding film 3 may be cured (see FIG. 1). When the pressure-sensitive adhesive layer 2 is cured by irradiation with radiation before it is pasted to the die-bonding film 3, the pressure-sensitive adhesive layer 2 is pasted to the die-bonding film 3 in a hard state. Therefore, excessive increase in adhesion is suppressed at the interface between the pressure-sensitive adhesive layer 2 and the die-bonding film 3. Accordingly, the anchoring effect between the pressure-sensitive adhesive layer 2 and the die-bonding film 3 can be decreased, and the peeling property can be improved.

The radiation curing-type pressure-sensitive adhesive 2 may be cured in advance according to the shape of the die-bonding film 3′ shown in FIG. 2. Accordingly, excessive increase in adhesion is suppressed at the interface between the pressure-sensitive adhesive layer 2 and the die-bonding film 3. As a result, the die-bonding film 3′ has a characteristic of easily peeling from the pressure-sensitive adhesive layer 2 during pickup. On the other hand, the other portion 2b of the pressure-sensitive adhesive layer 2 is not cured because it is not irradiated with radiation, and the adhesive strength is larger than that of the portion 2a. Accordingly, when a dicing ring is pasted to the other portion 2b, the dicing ring can be securely attached and fixed thereto.

As described above, in the pressure-sensitive adhesive layer 2 of the dicing die-bonding film 10 shown in FIG. 1, the portion 2b that is formed by a non-cured radiation curing-type pressure-sensitive adhesive adheres to the die-bonding film. 3, and the holding power during dicing can be secured. The radiation curing-type pressure-sensitive adhesive can support the die-bonding film 3 for fixing a semiconductor chip to an adherend such as a substrate with a good balance of adhesion and peeling. A dicing ring can be fixed on the portion 2b in the pressure-sensitive adhesive layer 2 of the dicing die-bonding film 11 shown in FIG. 2. The dicing ring made of metal such as stainless steel or a resin can be used for example.

The pressure-sensitive adhesive that configures the pressure-sensitive adhesive layer 2 is not especially limited. However, a radiation curing-type pressure-sensitive adhesive is suitable in the present invention. A radiation curing-type pressure-sensitive adhesive having a radiation curable functional group such as a carbon-carbon double bond and exhibiting adherability can be used without special limitation.

Example of the radiation curing-type pressure-sensitive adhesive layer includes adding type and radiation curing-type pressure-sensitive adhesives in which a radiation curable monomer component and a radiation curable oligomer component are compounded in a general pressure-sensitive adhesive such as an acrylic pressure-sensitive adhesive, a rubber pressure-sensitive adhesive, a silicone pressure-sensitive adhesive, and a polyvinylether pressure-sensitive adhesive. An acrylic pressure-sensitive adhesive containing an acrylic polymer as a base polymer is preferable as the pressure-sensitive adhesive from the viewpoint of cleaning and washing properties of an electronic part such as a semiconductor wafer or a glass part that dislike contamination with ultrapure water or an organic solvent such as alcohol.

Examples of the acrylic polymer include a polymer containing, as a monomer component, one or two or more kinds of: alkyl acrylate (for example, a straight chain or branched chain alkyl ester having 1 to 30 carbon atoms, and particularly 4 to 18 carbon atoms in the alkyl group such as methylester, ethylester, propylester, isopropylester, butylester, isobutylester, sec-butylester, t-butylester, pentylester, isopentylester, hexylester, heptylester, octylester, 2-ethylhexylester, isooctylester, nonylester, decylester, isodecylester, undecylester, dodecylester, tridecylester, tetradecylester, hexadecylester, octadecylester, and eicosylester) and cycloalkyl acrylate (for example, cyclopentylester, cyclohexylester, etc.). All of the words including “(meth)” in connection with the present invention have an equivalent meaning.

The acrylic polymer may optionally contain a unit corresponding to a different monomer component copolymerizable with the above-mentioned alkyl ester of (meth)acrylic acid or cycloalkyl ester thereof in order to improve the cohesive force, heat resistance or some other property of the polymer. Examples of such a monomer component include carboxyl-containing monomers such as acrylic acid, methacrylic acid, carboxyethyl (meth)acrylate, carboxypentyl (meth)acrylate, itaconic acid, maleic acid, fumaric acid, and crotonic acid; acid anhydride monomers such as maleic anhydride, and itaconic anhydride; hydroxyl-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxylmethylcyclohexyl)methyl (meth)acrylate; sulfonic acid group containing monomers such as styrenesulfonic acid, allylsulfonic acid, 2-(meth)acrylamide-2-methylpropanesulfonic acid, (meth)acrylamidepropanesulfonic acid, sulfopropyl (meth)acrylate, and (meth)acryloyloxynaphthalenesulfonic acid; phosphoric acid group containing monomers such as 2-hydroxyethylacryloyl phosphate; acrylamide; and acrylonitrile. These copolymerizable monomer components may be used alone or in combination of two or more thereof. The amount of the copolymerizable monomer (s) to be used is preferably 40% or less by weight of all the monomer components.

For crosslinking, the acrylic polymer can also contain multifunctional monomers if necessary as the copolymerizable monomer component. Such multifunctional monomers include hexane diol di(meth)acrylate, (poly)ethyleneglycol di(meth)acrylate, (poly)propylene glycol di(meth)acrylate, neopentyl glycol di(meth)acrylate, pentaerythritol di(meth)acrylate, trimethylol propane tri(meth)acrylate, pentaerythritol tri(meth)acrylate, dipentaerythritol hexa(meth)acrylate, epoxy (meth)acrylate, polyester (meth)acrylate, urethane (meth)acrylate etc. These multifunctional monomers can also be used as a mixture of one or more thereof. From the viewpoint of adhesiveness etc., the use amount of the multifunctional monomer is preferably 30 wt % or less based on the whole monomer components.

The acrylic polymer can be prepared by applying an appropriate method such as a solution polymerization method, an emulsion polymerization method, a bulk polymerization, or a suspension polymerization method to a mixture of at least one kind of component monomer. The pressure-sensitive adhesive layer preferably has composition in which the content of a low molecular weight substance is suppressed and preferably has an acrylic polymer having a weight average molecular weight of 300,000 or more, and especially 400,000 to 3,000,000 as a main component in respect of preventing wafer contamination, etc. Therefore, the pressure-sensitive adhesive can be an appropriate crosslinking type with an internal crosslinking method, an external crosslinking method, etc.

In order to control the crosslinking density of the pressure-sensitive adhesive layer 2, an appropriate method can be adopted such as a method of crosslinking treatment using an appropriate external crosslinking agent such as a multifunctional isocyanate compound, a multifunctional epoxy compound, a melamine compound, a metal salt compound, a metal chelate compound, an amino resin compound, or a peroxide or a method of crosslinking treatment by mixing a low molecular compound having two or more carbon-carbon double bonds and irradiating with an energy ray. When the external crosslinking agent is used, the used amount is appropriately determined by a balance with the base polymer to be crosslinked and further by the use as the pressure-sensitive adhesive. Generally, it is about 5 parts by weight or less, and preferably 0.1 to 5 parts by weight to 100 parts by weight of the base polymer. Further, various additives such as a tackifier and an antioxidant may be used in the pressure-sensitive adhesive other than the above-described components as necessary.

Examples of the radiation curing-type monomer component to be compounded include such as urethane(meth)acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxypenta(meth)acrylate, dipentaerythritol hexa(meth)acrylate, and 1,4-butane diol di(meth)acrylate. These components may be used alone or in combination of two or more thereof.

Further, the radiation curing-type oligomer component includes various types of oligomers such as an urethane based, a polyether based, a polyester based, a polycarbonate based, and a polybutadiene based oligomer, and its molecular weight is appropriately in a range of about 100 to 30,000. The compounding amount of the radiation curing-type monomer component and the oligomer component can be appropriately determined to an amount in which the adhesive strength of the pressure-sensitive adhesive layer can be decreased depending on the type of the pressure-sensitive adhesive layer. Generally, it is for example 5 to 500 parts by weight, and preferably about 70 to 150 parts by weight based on 100 parts by weight of the base polymer such as an acryl polymer constituting the pressure sensitive adhesive.

Further, besides the added type radiation curing-type pressure-sensitive adhesive described above, the radiation curing-type pressure-sensitive adhesive includes an internal radiation curing-type pressure-sensitive adhesive using an acryl polymer having a radical reactive carbon-carbon double bond in the polymer side chain, in the main chain, or at the end of the main chain as the base polymer. The internal radiation curing-type pressure-sensitive adhesives of an internally provided type are preferable because they do not have to contain the oligomer component, etc. that is a low molecular weight component, or most of them do not contain, they can form a pressure-sensitive adhesive layer having a stable layer structure without migrating the oligomer component, etc. in the pressure sensitive adhesive over time.

The above-mentioned base polymer, which has a carbon-carbon double bond, may be any polymer that has a carbon-carbon double bond and further has viscosity. As such a base polymer, a polymer having an acrylic polymer as a basic skeleton is preferable. Examples of the basic skeleton of the acrylic polymer include the acrylic polymers exemplified above.

The method for introducing a carbon-carbon double bond into any one of the above-mentioned acrylic polymers is not particularly limited, and may be selected from various methods. The introduction of the carbon-carbon double bond into a side chain of the polymer is easier in molecule design. The method is, for example, a method of copolymerizing a monomer having a functional group with an acrylic polymer, and then causing the resultant to condensation-react or addition-react with a compound having a functional group reactive with the above-mentioned functional group and a carbon-carbon double bond while keeping the radiation curability of the carbon-carbon double bond.

Examples of the combination of these functional groups include a carboxylic acid group and an epoxy group; a carboxylic acid group and an aziridine group; and a hydroxyl group and an isocyanate group. Of these combinations, the combination of a hydroxyl group and an isocyanate group is preferable from the viewpoint of the easiness of reaction tracing. If the above-mentioned acrylic polymer, which has a carbon-carbon double bond, can be produced by the combination of these functional groups, each of the functional groups may be present on any one of the acrylic polymer and the above-mentioned compound. It is preferable for the above-mentioned preferable combination that the acrylic polymer has the hydroxyl group and the above-mentioned compound has the isocyanate group. Examples of the isocyanate compound in this case, which has a carbon-carbon double bond, include methacryloyl isocyanate, 2-methacryloyloxyethyl isocyanate, and m-isopropenyl-α,α-dimethylbenzyl isocyanate. The used acrylic polymer may be an acrylic polymer copolymerized with anyone of the hydroxyl-containing monomers exemplified above, or an ether compound such as 2-hydroxyethyl vinyl ether, 4-hydroxybutyl vinyl ether or diethylene glycol monovinyl ether.

The intrinsic type radiation curable adhesive may be made only of the above-mentioned base polymer (in particular, the acrylic polymer), which has a carbon-carbon double bond. However, photopolymerizable compounds such as the above-mentioned radiation curable monomer component or oligomer component may be incorporated into the base polymer to such an extent that properties of the adhesive are not deteriorated. The blending amount of the photopolymerizable compound is usually 30 parts or less by weight, preferably from 0 to 10 parts by weight for 100 parts by weight of the base polymer.

The radiation curing-type pressure-sensitive adhesive preferably contains a photopolymerization initiator in the case of curing it with an ultraviolet ray or the like Examples of the photopolymerization initiator include α-ketol compounds such as 4-(2-hydroxyethoxy)phenyl(2-hydroxy-2-propyl)ketone, α-hydroxy-α,α′-methylacetophenone, 2-methyl-2-hydroxypropiophenone, and 1-hydroxycyclohexyl phenyl ketone; acetophenone compounds such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether compounds such as benzoin ethyl ether, benzoin isopropyl ether, and anisoin methyl ether; ketal compounds such as benzyl dimethyl ketal; aromatic sulfonyl chloride compounds such as 2-naphthalenesulfonyl chloride; optically active oxime compounds such as 1-phenyl-1,2-propanedione-2-(O-ethoxycarbonyl)oxime; benzophenone compounds such as benzophenone, benzoylbenzoic acid, and 3,3′-dimethyl-4-methoxybenzophenone; thioxanthone compound such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; acylphosphonoxides; and acylphosphonates. The amount of the photopolymerization initiator to be blended is, for example, from about 0.05 to 20 parts by weight for 100 parts by weight of the acrylic polymer or the like which constitutes the adhesive as a base polymer. However, in order to adjust the storage modulus of the pressure-sensitive adhesive layer 2 to within a range of 1×10⁷ to 5×10⁸ Pa, the amount of the photopolymerization initiator to be compounded is preferably 1 part by weight or more and 8 parts by weight or less, and more preferably 1 part by weight or more and 5 parts by weight or less to 100 parts by weight of the base polymer.

Further, examples of the radiation curing-type pressure-sensitive adhesive which is used in the formation of the pressure-sensitive adhesive layer 2 include such as a rubber pressure-sensitive adhesive or an acryl pressure-sensitive adhesive which contains an addition-polymerizable compound having two or more unsaturated bonds, a photopolymerizable compound such as alkoxysilane having an epoxy group, and a photopolymerization initiator such as a carbonyl compound, an organic sulfur compound, a peroxide, an amine, and an onium salt compound, which are disclosed in JP-A No. 60-196956. Examples of the above addition-polymerizable compound having two or more unsaturated bonds include such as polyvalent alcohol ester or oligoester of acryl acid or methacrylic acid and an epoxy or a urethane compound. Examples of the addition polymerizable compound having two or more unsaturated bonds include a polyhydric alcohol ester or oligoester of acrylic acid or methacrylic acid, an epoxy compound, and a urethane compound.

The amounts of the photopolymerizable compound and the photopolymerization initiator to be compounded are generally 10 to 500 parts by weight and 0.05 to 20 parts by weight, respectively, to 100 parts by weight of the base polymer. Besides these components to be compounded, an epoxy group functional crosslinking agent having at least one epoxy group in a molecular such as ethylene glycol diglycidyl ether may be additionally compounded as necessary to increase the crosslinking efficiency of the pressure-sensitive adhesive.

The pressure-sensitive adhesive layer 2 using a radiation curing-type pressure-sensitive adhesive can contain a compound that is colored by radiation irradiation as necessary. By containing the compound that is colored by radiation irradiation in the pressure-sensitive adhesive layer 2, only a portion irradiated with radiation can be colored. That is, the pressure-sensitive adhesive layer 2a that corresponds to the wafer pasting portion 3a can be colored. Therefore, whether the pressure-sensitive adhesive layer 2 is irradiated with radiation or not can be visually determined right away, and the wafer pasting portion 3a can be recognized easily, and the pasting of the semiconductor wafer is easy. Further, when detecting a semiconductor element with a photosensor or the like, the detection accuracy improves, and no false operation occurs during pickup of the semiconductor element.

The compound that colors by radiation irradiation is colorless or has a pale color before the irradiation. However, it is colored by irradiation with radiation. A preferred specific example of the compound is a leuco dye. Common leuco dyes such as triphenylmethane, fluoran, phenothiazine, auramine, and spiropyran dyes can be preferably used. Specific examples thereof include 3-[N-(p-tolylamino)]-7-anilinofluoran, 3-[N-(p-tolyl)-N-methylamino]-7-anilinofluoran, 3-[N-(p-tolyl)-N-ethylamino]-7-anilinofluoran, 3-diethylamino-6-methyl-7-anilinofluoran, crystal violet lactone, 4,4′,4″-trisdimethylaminotriphenylmethanol, and 4,4′,4″-trisdimethylaminotriphenylmethane.

Examples of a developer that is preferably used with these leuco dyes include a prepolymer of a conventionally known phenolformalin resin, an aromatic carboxylic acid derivative, and an electron acceptor such as activated white earth, and various color developers can be used in combination for changing the color tone.

The compound that is colored by irradiation with radiation like this may be included in a radiation curing-type pressure-sensitive adhesive after it is dissolved in an organic solvent, etc. at once or may be made into a powder to be included in the pressure-sensitive adhesive layer 2. The ratio of the compound to be used is 0.01 to 10% by weight, and preferably 0.5 to 5% by weight in the pressure-sensitive adhesive layer 2. When the ratio of the compound exceeds 10% by weight, the radiation that is irradiated to the pressure-sensitive achieve layer 2 is absorbed by the compound too much, and therefore the curing of the pressure-sensitive adhesive layer 2a becomes insufficient, and the adhesive strength may not decrease sufficiently. On the other hand, when the ratio of the compound is less than 0.01% by weight, the pressure-sensitive adhesive sheet may not be colored sufficiently when irradiating with radiation, and an incorrect operation may easily occur when the semiconductor element is picked up.

When the pressure-sensitive adhesive layer 2 is formed from the radiation curing-type pressure-sensitive adhesive, a method is exemplified in which the radiation curing-type pressure-sensitive adhesive layer 2 is formed on the support base material 1 and then a portion corresponding to the wafer pasting portion 3a is partially cured by irradiation with radiation to form the portion 2a corresponding to the wafer pasting portion 3a. The partial irradiation with radiation can be performed through a photo mask that has a pattern corresponding to the portion 3b or the like other than the wafer pasting portion 3a. Another example is a method of curing the layer by irradiation in spots. The formation of the radiation curing-type pressure-sensitive adhesive layer 2 can be performed by transferring a layer provided on a separator onto the support base material 1. The partial radiation curing can also be performed on the radiation curing-type pressure-sensitive adhesive layer 2 that is provided on the separator.

Further, when forming the pressure-sensitive adhesive layer 2 with a radiation curing-type pressure-sensitive adhesive, the pressure-sensitive adhesive layer 2a having a reduced adhesive strength can be formed by using at least one surface of the support base material 1 where the whole or part of the portion other than the portion corresponding to the wafer pasting portion 3a is protected from light, forming the radiation curing-type pressure-sensitive adhesive layer 2 on this surface, and curing the portion corresponding to the wafer pasting portion 3a by irradiation with radiation. As a light-shielding material, a material that is capable of serving as a photo mask on a supporting film can be produced by printing, vapor deposition, or the like. According to such a manufacturing method, the dicing die-bonding film of the present invention can be efficiently manufactured.

In case where curing inhibition due to oxygen occurs when irradiating with radiation, it is desirable to shut off oxygen (air) from the surface of the radiation curing-type pressure-sensitive adhesive layer 2. Examples of a method of shutting off oxygen include a method of coating the surface of the pressure-sensitive adhesive layer 2 with a separator and a method of irradiating with radiation such as an ultraviolet ray in a nitrogen gas atmosphere.

The die-bonding films 3 and 3′ each preferably has a water absorption rate of 1.5% by weight or less, more preferably 1.2% by weight or less, and especially preferably 1.0% by weight or less. By adjusting the water absorption rate of each of the die-bonding films 3 and 3′ to 1.5% by weight or less, the water content can be reduced that is absorbed by the die-bonding films 3 and 3′ from the dicing film while the dicing die-bonding films 10 and 11 are stored. As a result, the occurrence of reflow cracking in the reflow step can be further prevented. In addition, the water content that is absorbed by the die-bonding films 3 and 3′ can be reduced as well while the semiconductor package, in which the semiconductor chip is die-bonded on an adherend such as a lead frame by the die-bonding films 3 and 3′ and further sealed by a sealing resin, is stored. As the lower limit of the water absorption rate of each of the die-bonding films 3 and 3′ is lower, it is better from the viewpoint of the effect of the present invention. It is substantially 0%, and preferably 0%.

The water absorption rate of each of the die-bonding films 3 and 3′ can be controlled by performing optimization of manufacturing conditions, material design, etc.

The water absorption rate of the die-bonding films 3 and 3′ can be obtained as follows. A sample of 20 mm×20 mm is cut out from the die-bonding films 3 and 3′. The sample is left in a vacuum dryer at 120° C. for 3 hours to be dried. Then, it is left and cooled in a desiccator, and the dry weight M5 of the sample is measured. The sample is then left in a constant temperature and humidity chamber under an atmosphere of 85° C. and 85% RH for 120 hours to allow the sample to absorb moisture. Then, the sample is taken out and weighed. When the weighed value becomes constant, it is defined as M6. The water absorption rate is calculated based on the following formula (3) from the measured M5 and M6.

[Numerical Formula 8]

[(M6−M5)/M5]×100=Water absorption rate(% by weight) (3)

(wherein, M5 represents the initial weight of the die-bonding film, and M6 represents the weight after the die-bonding film is left under an atmosphere of 85° C. and 85% RH for 120 hours to absorb moisture.)

Example of the die-bonding films 3 and 3′ includes die-bonding films that are formed from a thermoplastic resin and a thermosetting resin, and specifically include die-bonding films that are formed from an epoxy resin, a phenol resin, and an acrylic resin.

The epoxy resin may be any epoxy resin that is ordinarily used as an adhesive composition. Examples thereof include bifunctional or polyfunctional epoxy resins such as bisphenol A type, bisphenol F type, bisphenol S type, brominated bisphenol A type, hydrogenated bisphenol A type, bisphenol AF type, biphenyl type, naphthalene type, fluorene type, phenol Novolak type, orthocresol Novolak type, tris-hydroxyphenylmethane type, and tetraphenylolethane type epoxy resins; hydantoin type epoxy resins; tris-glycicylisocyanurate type epoxy resins; and glycidylamine type epoxy resins. These may be used alone or in combination of two or more thereof. Among these epoxy resins, an epoxy resin having an aromatic ring such as a benzene ring, a biphenyl ring, or a naphthalene ring is especially preferable in the present invention. Specific examples thereof include a novolac type epoxy resin, a xylylene skeleton-containing phenol novolac type epoxy resin, a biphenyl skeleton-containing novolac epoxy resin, a bisphenol A type epoxy resin, a bisphenol F type epoxy resin, a tetramethylbiphenol type epoxy resin, and a triphenylmethane type epoxy resin. This is because these epoxy resins are rich in reactivity with a phenol resin as a curing agent and have excellent heat resistance, etc. An epoxy resin contains fewer impurities, etc. that erode a semiconductor element.

The epoxy resin preferably has a weight average molecular weight in a range of 300 to 1,500, and more preferably in a range of 350 to 1,000. When the weight average molecular weight is less than 300, the mechanical strength, heat resistance, and moisture resistance of the die-bonding film 3 after thermal curing may decrease. On the other hand, when the weight average molecular weight is more than 1,500, the die-bonding film after thermal curing may become rigid and brittle. The weight average molecular weight in the present invention means a value expressed in terms of polystyrene using a calibration curve of a standard polystyrene by gel permeation chromatography (GPC).

The phenol resin is a resin acting as a curing agent for the epoxy resin. Examples thereof include Novolak type phenol resins such as phenol Novolak resin, phenol biphenyl resin, phenol aralkyl resin, cresol Novolak resin, tert-butylphenol Novolak resin and nonylphenol Novolak resin; resol type phenol resins; and polyoxystyrenes such as poly (p-oxystyrene). These may be used alone or in combination of two or more thereof. Among these phenol resins, phenol Novolak resin and phenol aralkyl resin are preferable, since the connection reliability of the semiconductor device can be improved.

The phenol resin preferably has a weight average molecular weight in a range of 300 to 1,500, and more preferably in a range of 350 to 1,000. When the weight average molecular weight is less than 300, the thermal curing of the epoxy resin becomes insufficient, and sufficient toughness may not be obtained. On the other hand, when the weight average molecular weight is more than 1,500, the viscosity becomes high, and the workability of the die-bonding film at the time of production may decrease.

About the blend ratio between the epoxy resin and the phenol resin, for example, the phenol resin is blended with the epoxy resin in such a manner that the hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of the range, curing reaction therebetween does not advance sufficiently so that properties of the cured epoxy resin easily deteriorate.

The acrylic resin is not especially limited. However, a carboxyl group-containing acrylic copolymer and an epoxy group-containing acrylic copolymer are preferable in the present invention. Examples of a functional monomer that is used in the carboxyl group-containing acrylic copolymer include acrylic acid and methacrylic acid. The content of the acrylic acid or the methacrylic acid is adjusted so that the acid value becomes in a range of 1 to 4. For the remaining part, a mixture can be used of alkyl acrylate, alkyl methacrylate each having an alkyl group of 1 to 8 carbon atoms such as methyl acrylate and methyl methacrylate, and styrene, acrylonitrile, etc. Among these, ethyl(meth)acrylate and/or butyl(meth)acrylate are/is especially preferable. The mixing ratio is preferably adjusted by considering the glass transition point (T_{g}) of the acrylic resin described later. The polymerization method is not especially limited, and a conventionally known method can be adopted such as a solution polymerization method, a bulk polymerization method, a suspension polymerization method, or an emulsion polymerization method.

Other monomers that can be copolymerized with the above-described monomer component are not especially limited, and examples thereof include acrylonitrile, etc. The amount of these copolymerizable monomer components to be used is preferably in a range of 1 to 20% by weight to all the monomer components. By including other monomer components in the described range, cohesive strength, tackiness, etc. can be modified.

The polymerization method of the acrylic resin is not especially limited, and a conventionally known method can be adopted such as a solution polymerization method, a bulk polymerization method, a suspension polymerization method, or an emulsion polymerization method.

The acrylic resin preferably has a glass transition point (T_{g}) of −30 to 30° C., and more preferably −20 to 15° C. By adjusting the glass transition point to −30° C. or higher, the heat resistance can be secured. On the other hand, by adjusting it to 30° C. or lower, the effect of preventing chip fly of a wafer having a rough surface after dicing can be improved.

The acrylic resin preferably has a weight average molecular weight of 100,000 to 1,000,000, and more preferably 350,000 to 900,000. By adjusting the weight average molecular weight to 100,000 or more, excellent tackiness to the surface of the adherend can be obtained at high temperature, and the heat resistance can be also improved. On the other hand, by adjusting the weight average molecular weight to 1,000,000 or less, the acrylic resin can be easily dissolved in an organic solvent.

A filler may be added to the die-bonding films 3 and 3′. Examples of the filler include an inorganic filler and an organic filler. An inorganic filler is preferred from the viewpoints of improving handling property and thermal conductivity, adjusting melt viscosity, and imparting thixotropic property.

The inorganic filler is not especially limited, and examples thereof include silica, aluminum hydroxide, calcium hydroxide, magnesium hydroxide, antimony trioxide, calcium carbonate, magnesium carbonate, calcium silicate, magnesium silicate, calcium oxide, magnesium oxide, aluminum oxide, aluminum nitride, aluminum borate, boron nitride, crystalline silica, and amorphous silica. These can be used alone or two or more thereof can be used in combination. From the viewpoint of improving heat conductivity, aluminum oxide, aluminum nitride, boron nitride, crystalline silica, amorphous silica, etc. are preferred. From the viewpoint of a balance with the tackiness of the die-bonding film 3, silica is preferable. Examples of the organic filler include polyimide, polyamideimide, polyetheretherketone, polyetherimide, polyesterimide, nylon, and silicone. These can be used alone or two or more thereof can be used in combination.

The filler preferably has an average particle diameter of 0.005 to 10 μm, and more preferably 0.05 to 1 μm. When the filler has an average particle diameter of 0.005 μm or more, good wettability to the adherend can be obtained, and a decrease in tackiness can be suppressed. On the other hand, by adjusting the average particle diameter to 10 μm or less, a reinforcement effect to the die-bonding films 3 and 3′ due to addition of the filler is enhanced, and the heat resistance can be improved. Fillers each having a different average particle diameter may be combined and used. The average particle diameter of the filler can be obtained with a laser diffraction/scattering type particle size distribution meter (apparatus name: LA-910, manufactured by HORIBA, Ltd.)

The shape of the filler is not especially limited, and for example, those having spherical shape and ellipsoid can be used.

When the total weight of the epoxy resin, the phenol resin, and the acrylic resin is defined as “A parts by weight” and the weight of the filler is defined as “B parts by weight,” the ratio B/(A+B) is preferably 0.1 or more, more preferably 0.2 to 0.8, and especially preferably 0.2 to 0.6. By adjusting the amount of the filler to be compounded to 0.1 or more to the total weight of the epoxy resin, the phenol resin, and the acrylic resin, the storage modulus of the die-bonding film 3 at 23° C. can be adjusted to 5 MPa or more.

If necessary, other additives besides the inorganic filler may be incorporated into the adhesive layer 3, 3′ of the present invention. Examples thereof include a flame retardant, a silane coupling agent, and an ion trapping agent.

Examples of the flame retardant include antimony trioxide, antimony pentaoxide, and brominated epoxy resin. These may be used alone or in combination of two or more thereof.

Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These may be used alone or in combination of two or more thereof.

Examples of the ion trapping agent include hydrotalcite and bismuth hydroxide. These may be used alone or in combination of two or more thereof.

A thermal curing-accelerating catalyst for the epoxy resin and the phenol resin is not especially limited, and for example, salts composed of any of a triphenylphosphine skeleton, an amine skeleton, a triphenylborane skeleton, and trihalogenborane skeleton are preferred.

From the viewpoint of decreasing the maximum value of the peeling strength in the vicinity of the cut surface when the dicing film is peeled from the die-bonding films 3 and 3′, for example, die-bonding films 3 and 3′ are preferably formed with the filler having a content of 30% by weight or more. When the die-bonding film 3 is formed with the filler having a content of 30% by weight or more, burrs that are generated from a part of the die-bonding film 3 at the cut surface by dicing can be prevented from attaching to the boundary between the pressure-sensitive adhesive layer 2 and the die-bonding film 3.

The thickness of the die-bonding film 3, 3′ (in the case that the film is a laminate, the total thickness thereof) is not particularly limited, and is, for example, from about 5 to 100 μm, preferably from about 5 to 50 μm.

The die-bonding films 3 and 3′ can be configured of only a single layer of the adhesive layer. Thermoplastic resins each having a different glass transition temperature and thermosetting resins each having a different thermal curing temperature may be appropriately combined to make a multilayer structure with two layers or more. Because cutting water is used in the dicing step of the semiconductor wafer, the die-bonding film absorbs moisture, and the water content rate may become equal to or more than normal state. When the die-bonding film is attached to a substrate, etc. with such a high water content rate, water vapor collects in the adhesion interface at a stage of after cure, and floating may occur. Therefore, the die-bonding film is made to have a configuration in which a core material having high moisture permeability is sandwiched with the adhesive layers to diffuse water vapor through the film at the stage of after-cure, and the above mentioned problem can be avoided. From such a viewpoint, the die-bonding films 3 and 3′ may have a multilayer structure in which the adhesive layer is formed on one surface or both surfaces of the core material.

Examples of the core material include a film (for example, a polyimide film, a polyester film, a polyethylene terephthalate film, a polyethylene naphthalate film, or a polycarbonate film); a resin substrate reinforced with glass fibers or plastic nonwoven fibers; a mirror silicon wafer; a silicon substrate; and a glass substrate.

The die-bonding films 3 and 3′ are preferably protected by a separator (not shown). The separator has a function as a protecting material that protects the die-bonding film until it is put to practical use. The separator can be also used as a support base material when the die-bonding films 3 and 3′ are transferred to the dicing film. The separator is peeled when the semiconductor wafer is pasted onto the die-bonding films 3 and 3′. As the separator, a polyethylene terephthalate (PET) film, a polyethylene film, a polypropylene film, a plastic film in which the surface thereof is coated with a release agent such as a fluorine release agent or a long chain alkyl acrylate release agent, paper, etc. can be used.

### (Method of Manufacturing Semiconductor Device)

A method of manufacturing a semiconductor device using a dicing die-bonding film 10 shown in FIG. 1 will be described.

First, a semiconductor wafer 4 is press-adhered on the wafer pasting portion 3a of the die-bonding film. 3 in the dicing die-bonding film 10, and it is fixed by adhering and holding (mounting step). The present step is performed while pressing with a pressing means such as a pressing roll. The laminating temperature at the time of mounting is not particularly limited and is, for example, preferably within a range from 20 to 80° C.

Then, the semiconductor wafer 4 is diced. At this time, a dicing ring is pasted on a portion 3b other than the wafer pasting portion 3a of the die-bonding film 3. The semiconductor wafer 4 is cut into a prescribed size to be formed into individual pieces through the dicing, and a semiconductor chip 5 is manufactured. The dicing is performed from the side of the circuit surface of the semiconductor wafer 4. At this time, the dicing die-bonding film 10 is cut with a dicing blade until the die-bonding film 3 is completely cut and at least a part of the pressure-sensitive adhesive layer 2 is cut. However, it is not preferable that the pressure-sensitive adhesive layer 2 is completely cut and the cut reaches the support base material 1 because threadlike debris may be generated.

The dicing apparatus used in the dicing step is not particularly limited, and a conventionally known apparatus can be used. Further, because the semiconductor wafer 4 is adhered and fixed by the dicing die-bonding film 10, chip crack and chip fly can be suppressed, and at the same time the damage of the semiconductor wafer 4 can be also suppressed.

Pickup of the semiconductor chip is performed in order to peel a semiconductor chip that is adhered and fixed to the dicing die-bonding film 10. The method of picking up is not particularly limited. Examples include a method of pushing up the individual semiconductor chip 5 from the dicing die-bonding 10 side with a needle and picking up the pushed semiconductor chip with a picking-up apparatus.

When the pressure-sensitive adhesive layer 2 is of a radiation curing type and is not cured, the pickup is preferably performed after irradiating the pressure-sensitive adhesive layer 2 with radiation. When the pressure-sensitive adhesive layer 2 is of a radiation curing type and is completely cured in advance, the pickup is performed without irradiating with radiation. In either case, the semiconductor chip can be easily peeled because the adhesive strength of the pressure-sensitive adhesive layer 2 to the die-bonding film 3 is lowered. As a result, the pickup becomes possible without damaging the semiconductor chip. The conditions such as irradiation intensity and the irradiation time when irradiating with radiation are not especially limited, and they can be appropriately set as necessary.

Next, the semiconductor chip that is formed by dicing is die-bonded to an adherend with the die-bonding film 3a interposed. The die-bonding is performed by pressure bonding. The condition of the die-bonding is not especially limited, and can be appropriately set. Specifically, the die-bonding can be performed at a die bond temperature of 80 to 160° C., a die-bonding pressure of 5 to 15 N, and a bonding time of 1 to 10 seconds, for example.

Examples of the adherend include a lead frame, a TAB film, a substrate, and a semiconductor chip that is produced separately. The adherend may be a deformable adherend that can be easily deformed or may be a non-deformable adherend (such as a semiconductor wafer) that is difficult to be deformed. A conventionally known substrate can be used as the substrate. Further, a metal lead frame such as a Cu lead frame and a 42 Alloy lead frame and an organic substrate composed of glass epoxy, BT (bismaleimide-triazine), and polyimide can be used as the lead frame. However, the present invention is not limited to this, and includes a circuit substrate that can be used by mounting a semiconductor element and electrically connecting with the semiconductor element.

Then, the die-bonding film 3a is thermally cured by performing a heat treatment, and the semiconductor chip is adhered to the adherend. The condition of the heat treatment is a temperature of 80 to 180° C. and a heating time of 0.1 to 24 hours, preferably 0.1 to 4 hours, and more preferably 0.1 to 1 hour.

Next, a wire bonding step of electrically connecting the tip of a terminal part (inner lead) of the adherend 6 with an electrode pad (not shown) on the semiconductor chip with a bonding wire is performed. The bonding wires may be, for example, gold wires, aluminum wires, or copper wires. The temperature when the wire bonding is performed is from 80 to 250° C., preferably from 80 to 220° C. The heating time is from several seconds to several minutes. The connection of the wires is performed by using a combination of vibration energy based on ultrasonic waves with compression energy based on the application of pressure in the state that the wires are heated to a temperature in the above-mentioned range.

Then, a sealing step sealing the semiconductor chip with a sealing resin is performed. This step is performed for protecting the semiconductor chip that is loaded on the adherend and the bonding wire. This step is performed by molding a resin for sealing with a mold. An example of the sealing resin is an epoxy resin. The heating temperature during the resin sealing is normally 175° C. and it is performed for 60 to 90 seconds. However, the present invention is not limited thereto, and the curing can be performed at 165 to 185° C. for a few minutes, for example. With this operation, the sealing resin is cured. In the present invention, when a heat treatment is performed to thermally cure the die-bonding film 3 in the die-bonding step, voids between the die-bonding film 3 and the adherend can be eliminated after the sealing step.

The sealing resin that is insufficiently cured in the sealing step is completely cured in the post curing step. The heating temperature in this step differs depending on the type of the sealing resin. However, it is in a range of 165 to 185° C., and the heating time is about 0.5 to 8 hours. Accordingly, a semiconductor package can be obtained.

Even when a moisture and solder reflow resistance test is performed, the semiconductor package that is obtained in such way has high reliability to endure the test. The moisture and solder reflow resistance test is performed with a conventionally known method.

Then, the semiconductor package is surface-mounted on a printed circuit board. An example of a method of surface-mounting includes reflow soldering in which the solder is supplied onto the printed circuit board in advance and soldering is then performed while heating and melting the solder by warm air or the like. Examples of the heating method include hot air reflow and infrared reflow. It may be any method of a whole heating method and a local heating method. The heating temperature is preferably 240 to 265° C. and the heating time is preferably 1 to 20 seconds.

### EXAMPLES

Suitable examples of the present invention will be described in detail below. However, the invention is not limited to these examples.

### Example 1

### [Production of Die-Bonding Film]

3 parts by weight of a multifunctional isocyanate crosslinking agent, 23 parts by weight of an epoxy resin (Epicoat 1004, manufactured by Japan Epoxy Resins Co., Ltd.), and 6 parts by weight of a phenol resin (Milex XLC-CC, manufactured by Mitsui Chemicals, Inc.) were dissolved in methylethylketone with respect to 100 parts of an acrylic ester polymer (Paracron W-197CM, manufactured by Negami chemical Industries Co., Ltd.) having ethyl acrylate-methyl methacrylate as a main component, to prepare a solution of an adhesive composition having a concentration of 20% by weight.

The solution of an adhesive composition was applied onto a release-treated film composed of a polyethylene terephthalate film as a release liner (thickness 50 μm) on which a silicone release treatment was performed. Then, it was dried at 120° C. for 3 minutes to produce a die-bonding film A having a thickness of 25 μm on the release-treated film.

### [Production of Dicing Film]

First, a radiation curing-type acrylic pressure-sensitive adhesive was prepared. That is, 70 parts by weight of butyl acrylate, 30 parts by weight of ethyl acrylate, and 5 parts by weight of acrylic acid were copolymerized in ethyl acetate in accordance with a routine method to obtain a solution of an acrylic polymer having a weight average molecular weight of 800,000 and a concentration of 30% by weight.

Then, 20 parts by weight of dipentaerythritol monohydroxypentaacrylate as a photopolymerizable compound and 1 part by weight of α-hydroxycyclohexylphenylketone as a photopolymerization initiator were compounded in the solution of an acrylic polymer. The obtained solution was dissolved uniformly in toluene to produce a solution of a radiation curing-type acrylic pressure-sensitive adhesive having a concentration of 25% by weight.

Subsequently, the solution of a radiation curing-type acrylic pressure-sensitive adhesive was applied on a support base material composed of a polyethylene film (water absorption rate: 0.06%) having a thickness of 60 μm. It was then dried to form a pressure-sensitive adhesive layer having a thickness of 20 μm on the polyethylene film.

Further, only a portion corresponding to a wafer pasting portion on the pressure-sensitive adhesive layer was irradiated with an ultraviolet ray of 500 mJ/cm² (accumulated light amount of ultraviolet ray) to produce a dicing film A in which the corresponding portion was cured with an ultraviolet ray.

### [Production of Dicing Die-Bonding Film]

The die-bonding film A was transferred onto the pressure-sensitive adhesive layer of the dicing film A to produce a dicing die-bonding film A according to the present example.

### Example 2

### [Production of Die-Bonding Film]

In Example 2, a die-bonding film B (thickness 50 μm) according to Example 2 was produced in the same manner as in Example 1 except that a polymer (Paracron SN-710, manufactured by Negami chemical Industries Co., Ltd.) having butyl acrylate as a main component was used instead of the acrylic ester polymer used in Example 1.

### [Production of Dicing Film]

First, a radiation curing-type acrylic pressure-sensitive adhesive was prepared. That is, compounded compositions obtained by compounding 50 parts by weight of ethyl acrylate, 50 parts by weight of butyl acrylate, and 16 parts by weight of 2-hydroxyethyl acrylate were copolymerized in toluene to obtain a solution of an acrylic polymer having a weight average molecular weight of 500,000 and a concentration of 35% by weight.

Then, the solution of an acrylic polymer was subjected to an addition reaction with 20 parts by weight of 2-methacryloyloxyethylisocyanate to introduce a carbon-carbon double bond to a side chain within the polymer molecule. To 100 parts by weight (solid content) of the polymer thus obtained were compounded 1 part by weight of a polyisocyanate crosslinking agent and 3 parts by weight of an acetophenone photopolymerization initiator, and then the resultant solution was uniformly dissolved in toluene to produce a solution of a radiation curing-type acrylic pressure-sensitive adhesive having a concentration of 23% by weight.

Subsequently, the solution of a radiation curing-type acrylic pressure-sensitive adhesive was applied on a support base material composed of a polyethylene film (water absorption rate: 0.07%) having a thickness of 80 μm. It was then dried to form a pressure-sensitive adhesive layer having a thickness of 5 μm on the polyethylene film.

Further, only a portion corresponding to a wafer pasting portion on the pressure-sensitive adhesive layer was irradiated with an ultraviolet ray of 500 mJ/cm² (accumulated light amount of ultraviolet ray) to produce a dicing film B in which the corresponding portion was cured with an ultraviolet ray.

### [Production of Dicing Die-Bonding Film]

The die-bonding film B was transferred onto the pressure-sensitive adhesive layer of the dicing film B to produce a dicing die-bonding film B according to the present example.

### Comparative Example 1

In the present comparative example, a dicing die-bonding film C according to the present comparative example was produced in the same manner as in Example 1 except that the photopolymerizable compound was changed to ethylene glycol diacrylate and its amount to be compounded was changed to 40 parts by weight.

### Comparative Example 2

In the present comparative example, a dicing die-bonding film D according to the present comparative example was produced in the same manner as in Example 1 except that the photopolymerizable compound was changed to ethylene glycol diphenyl acrylate and its amount to be compounded was changed to 30 parts by weight.

### (Water Absorption Rate)

The water absorption rates of the dicing die-bonding films A to D obtained in the examples and the comparative examples were measured with a method shown below. The results are shown in Table 1. That is, a sample of 20 mm×20 mm was cut out from each of the dicing die-bonding films A to D. The sample was left in a vacuum dryer at 120° C. for 3 hours to be dried. Then, it was left and cooled in a desiccator, and the dry weight M1 of the sample was measured. The sample was then left in a constant temperature and humidity chamber under an atmosphere of 85° C. and 85% RH for 120 hours to allow the sample to absorb moisture. Then, the sample was taken out and weighed. When the weighed value became constant, it was defined as M2. The water absorption rate was calculated based on the following formula (1) from the measured M1 and M2.

[Numerical Formula 9]

[(M2−M1)/M1]×100=Water absorption rate(% by weight) (1)

(wherein, M1 represents the initial weight of the dicing die-bonding film, and M2 represents the weight after the dicing die-bonding film is left under an atmosphere of 85° C. and 85% RH for 120 hours to absorb moisture.)

The water absorption rates of the dicing films A to D obtained in the examples and the comparative examples were measured with a method shown below. The results are shown in Table 1. That is, a sample of 20 mm×20 mm was cut out from each of the dicing films A to D. The sample was left in a vacuum dryer at 120° C. for 3 hours to be dried. Then, it was left and cooled in a desiccator, and the dry weight M3 of the sample was measured. The sample was then left in a constant temperature and humidity chamber under an atmosphere of 85° C. and 85% RH for 120 hours to allow the sample to absorb moisture. Then, the sample was taken out and weighed. When the weighed value became constant, it was defined as M4. The water absorption rate was calculated based on the following formula (2) from the measured M3 and M4.

[Numerical Formula 10]

[(M4−M3)/M3]×100=Water absorption rate(% by weight) (2)

(wherein, M3 represents the initial weight of the dicing film, and M4 represents the weight after the dicing film is left under an atmosphere of 85° C. and 85% RH for 120 hours to absorb moisture.)

The water absorption rates of the die-bonding films A and B obtained in the examples and the comparative examples were measured with a method shown below. The results are shown in Table 1. That is, a sample of 20 mm×20 mm was cut out from each of the die-bonding films A and B. The sample was left in a vacuum dryer at 120° C. for 3 hours to be dried. Then, it was left and cooled in a desiccator, and the dry weight M5 of the sample was measured. The sample was left in a constant temperature and humidity chamber under an atmosphere of 85° C. and 85% RH for 120 hours to allow the sample to absorb moisture. Then, the sample was taken out and weighed. When the weighed value became constant, it was defined as M6. The water absorption rate was calculated based on the following formula (3) from the measured M5 and M6.

[Numerical Formula 11]

[(M6−M5)/M5]×100=Water absorption rate(% by weight) (3)

(wherein, M5 represents the initial weight of the die-bonding film, and M6 represents the weight after the die-bonding film is left under an atmosphere of 85° C. and 85% RH for 120 hours to absorb moisture.)

### (Moisture and Solder Reflow Resistance)

Each of the dicing die-bonding films A to D obtained in the examples and the comparative examples was mounted to a semiconductor wafer. A semiconductor wafer was used having a size of 8 inch and on which backside grinding was performed so that it had a thickness of 75 μm. The grinding conditions and the pasting conditions are as follows. “Permeation of water into interface between dicing film and die-bonding film” was also evaluated during the procedure of evaluating “moisture and solder reflow resistance”.

### <Wafer Grinding Conditions>

Grinding apparatus: DGP-8760, manufactured by DISCO Corporation

Semiconductor wafer: 8 inch diameter (backside grinding was performed from thickness of 750 μm to 75 μm)

### <Pasting Conditions>

Pasting apparatus: DR-3000II, manufactured by Nitto Seiki Co., Ltd.

Pasting speed: 100 mm/minute

Pasting pressure: 0.3 MPa

Stage temperature at pasting: 23° C.

Then, the semiconductor wafer was diced to form semiconductor chips. The dicing was performed so that the chip size became 10 mm square. The dicing conditions are as follows.

### <Dicing Condition>

Dicing apparatus: DFD-6361, manufactured by DISCO Corporation

Dicing speed: 30 mm/second

Dicing blade:
Z1: 2050-HEDD, manufactured by DISCO Corporation
Z2: 2050-HCBB, manufactured by DISCO Corporation

Rotating speed: 40,000 rpm

Cut amount of Z2 into dicing tape: 20 μm

Cutting method: Step cut/A mode

Chip size: 10 mm square

An expanding step was performed by expanding each of the dicing die-bonding films to form a predetermined space between the chips. The expanding conditions are as follows.

### <Expanding Conditions>

Die bonder: Apparatus name: SPA-300, manufactured by Shinkawa Ltd.

Drawing amount of outer ring to inner ring: 3 mm

Dicing ring: 2-8-1

(Permeation of Water into Interface Between Dicing Film and Die-Bonding Film)

After dicing, whether or not the permeation of water into the interface between the dicing film and the die-bonding film was confirmed with an optical microscope (50× magnification). Because it was difficult to confirm the interface between the dicing film and the die-bonding film from the cut surface side immediately after dicing, the permeation of water was confirmed after expanding.

The semiconductor chip with a die-bonding film was picked up with a pushup method from the base side of each dicing die-bonding film with a needle. The pickup conditions are as follows.

### <Pickup Condition>

Die bonder: Apparatus name: SPA-300, manufactured by Shinkawa Ltd.

Number of needles: 9 needles

Needle pushing distance: 350 μm (0.35 mm)

Needle pushing speed: 5 mm/second

Absorption maintaining time: 80 ms

The semiconductor chip that had been picked up was die-bonded on a substrate. The die-bonding conditions were as follows: stage temperature of 150° C., load of 15 N, and loading time of 1 second. The configuration of the substrate is as shown in Table 1.

Then, the substrate in which the semiconductor chip was die-bonded was subjected to a heat treatment in a drier at 150° C. for 1 hour to thereafter package it with a sealing resin (product name: GE-100, manufactured by Nitto Denko Corporation). The sealing conditions were as follows: molding temperature of 175° C. and molding time of 90 seconds. A post curing step was performed on the obtained semiconductor package. Specifically, the heating temperature was set to 175° C. and the heating time was set to 1 hour. Accordingly, 10 chip array type ball grid array semiconductor packages (12=long×12 mm wide×0.6=thick) were produced.

Subsequently, the moisture absorption of the semiconductor package was performed under conditions of 60° C., 60% RH, and 120 hours. After that, the semiconductor package was placed in an IR reflow furnace that was set to a preheating temperature of 150±30° C., a preheating time of 90 seconds, a peak temperature of 260° C. or higher, and a heating time at the peak temperature of 10 seconds. Then, the semiconductor package was cut with a glass cutter, and the cross section thereof was observed with an ultrasonic microscope to confirm the occurrence of peeling at the boundary of each of the die-bonding films A to D and the substrate. The confirmation was performed on 10 semiconductor chips and the semiconductor chips in which peeling occurred were counted.

TABLE 1

| | | Material/Conditions, etc. |
|---|---|---|
| Semiconductor | Type | Chip Array Type Ball Grid Array |
| Package | Size | 12 mm × 12 mm × 0.6 mm |
| | Number | 10 |
| Substrate | Core Material | Glass Epoxy |
| | Thickness of Core | 100 μm |
| | Material | |
| | Thickness of | 35 μm |
| | Circuit | |
| | Solder Resist | PSR4000-AUS303 (Manufactured |
| | Material | by Taiyo Ink MFG. Co., Ltd.) |
| | Thickness of | 20 μm to 30 μm |
| | Solder Resist | |
| Semiconductor | Size | 1 mm × 1 mm × 0.1 mm |
| Chip | | |
| Die-bonding | Stage Temperature | 150° C. |
| Conditions | Load | 15 N |
| | Load Temperature | 1 second |
| Die Bond | Temperature | 150° C. |
| Curing | Time | 1 hour |
| Resin Sealing | Sealing Resin | GE-100 (Manufactured by Nitto |
| | | Denko Corporation) |
| | Molding | 175° C. |
| | Temperature | |
| | Molding Time | 90 seconds |
| | Post Curing | 175° C. × 1 hour |
| Moisture Absorption Conditions | | 60° C./60% RH × 120 hours |
| (Semiconductor Package) | | |
| Reflow | Method | Infrared Ray |
| Conditions | Preheating | 150 ± 30° C. × 90 seconds |
| | Peak Temperature | 260° C. or higher × 10 seconds |

### (Result)

As clear from Table 2, it was confirmed that the die-bonding film of each of the dicing die-bonding films C and D according to Comparative Examples 1 and 2 after the reflow step was peeled from the semiconductor chip although the water absorption rates of the die-bonding films of the dicing die-bonding films C and D were suppressed to 1.5% by weight or less, respectively. This is considered to be caused by a large water absorption rate of the dicing film. In addition, it was confirmed that water had penetrated into the interface between the dicing film and the die-bonding film of the dicing die-bonding film C according to Comparative Example 1 after the dicing step.

In contrast, as a result of decreasing the water absorption rate of the dicing film of each of the dicing die-bonding films A and B according to Examples 1 and 2, it was not confirmed that the die-bonding film after the reflow step was peeled from the semiconductor chip. And, the moisture and solder reflow resistance was improved. In addition, it was confirmed that water permeation was prevented at the interface between the dicing film and the die-bonding film as well after the dicing step.

TABLE 2

| | | | Comparative | Comparative |
|---|---|---|---|---|
| | Example 1 | Example 2 | Example 1 | Example 2 |
| Water Absorption | 0.2 | 0.1 | 3.1 | 2.4 |
| Rate (%) of Dicing | | | | |
| Film | | | | |
| Water Absorption | 0.34 | 0.45 | 2.1 | 1.9 |
| Rate (%) of Dicing | | | | |
| die-bonding film | | | | |
| Water Absorption | 0.5 | 0.8 | — | — |
| Rate (%) of Die- | | | | |
| bonding film | | | | |
| Number of Peeling | 0 | 0 | 10 | 9 |
| Occurrences after | | | | |
| Reflow Step | | | | |
| Occurrence of | Absence | Absence | Presence | Absence |
| Water Permeation | | | | |
| into Interface* | | | | |

*Presence or absence of water Permeation into interface between dicing film and die-bonding film after dicing is shown.

1. A dicing die-bonding film, comprising at least:
a dicing film in which a pressure-sensitive adhesive layer is provided on a support base material; and
a die-bonding film that is provided on the pressure-sensitive adhesive layer, wherein
the dicing die-bonding film has a water absorption rate of 1.5% by weight or less calculated from the following formula (1):
[(M2−M1)/M1]×100=Water absorption rate(% by weight) (1)
wherein, M1 represents the initial weight of the dicing die-bonding film, and M2 represents the weight after the dicing die-bonding film is left under an atmosphere of 85° C. and 85% RH for 120 hours to absorb moisture.

2. The dicing die-bonding film according to claim 1, wherein the dicing film has a water absorption rate of 1.5% by weight or less calculated from the following formula (2):
[(M4−M3)/M3]×100=Water absorption rate(% by weight) (2)
wherein, M3 represents the initial weight of the dicing film, and M4 represents the weight after the dicing film is left under an atmosphere of 85° C. and 85% RH for 120 hours to absorb moisture.

3. The dicing die-bonding film according to claim 1, wherein the die-bonding film has a water absorption rate of 1.5% by weight or less calculated from the following formula (3):
[(M6−M5)/M5]×100=Water absorption rate(% by weight) (3)
wherein M5 represents the initial weight of the die-bonding film, and M6 represents the weight after the die-bonding film is left under an atmosphere of 85° C. and 85% RH for 120 hours to absorb moisture.

4. The dicing die-bonding film according to claim 2, wherein the die-bonding film has a water absorption rate of 1.5% by weight or less calculated from the following formula (3):
[(M6−M5)/M5]×100=Water absorption rate(% by weight) (3)
wherein, M5 represents the initial weight of the die-bonding film, and M6 represents the weight after the die-bonding film is left under an atmosphere of 85° C. and 85% RH for 120 hours to absorb moisture.

5. A method of manufacturing a semiconductor device, comprising:
attaching a the dicing die-bonding film of claim 1 to a semiconductor wafer; and
dicing the semiconductor wafer and the die-bonding film adhered to the semiconductor wafer.

6. The method of manufacturing a semiconductor device according to claim 5, further comprising:
peeling a semiconductor chip and attached die-bonding film produced by the dicing from the pressure-sensitive adhesive layer; and
attaching the semiconductor chip to a substrate via the attached die-bonding film; and
wire bonding the semiconductor chip.
